(19) United States
(12) Patent Application Publication
(10) Pub. No.: US 2011/0014881 A1
(43) Pub. Date: Jan. 20, 2011

(54) MULTI-FUNCTIONAL COMMUNICATION MODULE

(76) Inventor: Cheng-Hsu Yang, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/642,864

(22) Filed: Dec. 21, 2009

Related U.S. Application Data
(60) Provisional application No. 61/226,294, filed on Jul. 17, 2009.

(51) Int. Cl. H04W 88/02; H04B 1/38; H05K 7/20

(52) U.S. Cl. 455/90.3; 361/704

(57) ABSTRACT

A multi-functional communication module includes a base, a plurality of wireless communication elements disposed on the base, a plurality of antennas electrically connected to the plurality of wireless communication elements respectively so as to transmit wireless signals of the plurality of wireless communication elements, and a heat conductive component. A side of the heat conductive component is connected to the plurality of wireless communication elements so as to dissipate heat generated by the plurality of wireless communication elements.

### CROSS REFERENCE TO RELATED APPLICATIONS

The application claims the benefit of U.S. Provisional Application No. 61/226,294, which was filed on Jul. 17, 2009.

### BACKGROUND OF THE INVENTION

1. Field of the Invention

The present invention relates to a communication module, and more particularly, to a multi-functional communication module for integrating a plurality of wireless communication elements.

2. Description of the Prior Art

A conventional notebook computer includes a plurality of wireless communication elements, an antenna, and a plurality of transmission cables for setting a wireless communication module. The plurality of wireless communication elements is disposed on a main board of a host, the antenna is installed on a lateral side of a liquid crystal display of a display module, and the plurality of transmission cables is electrically connected with the plurality of wireless communication elements and the antenna, respectively, for transmitting signals. The host and the display module need to have larger space to contain the plurality of transmission cables, which is disposed inside the space complicatedly though. Two ends of the transmission cables are electrically connected to the wireless communication elements disposed inside the host and the antenna disposed inside the display module, respectively, so that the signals transmitted by the transmission cables with long length are lost easily and are interfered by electromagnetic interference easily when the transmission cables are set adjacent to additional electronic elements. In addition, dimension of the host of the conventional notebook computer is often limited to dimensions of elements of the wireless communication module. For example, a larger space is formed inside the host and the display module of the conventional notebook computer for containing the elements of the wireless communication module, such as the plurality of transmission cables disposed complicatedly, and height of the larger space is limited to predetermined heights of the elements of the wireless communication module.

Especially, different wireless communication elements are interfered with each other easily when the signals are transmitted in the same communication frequency band. Although Co-Existence design and time sharing design techniques can solve the above-mentioned drawback by distributing operating periods of a central processing unit for the plurality of wireless communication elements and the plurality of antennas, the above-mentioned mechanism decreases transmission efficiency of the plurality of wireless communication elements accordingly. Besides, heat generated by the plurality of wireless communication elements increases temperature of the main board, decreases heat dissipating efficiency of a fan disposed on the main board, and decreases operating efficiency of the main board. Thus, design of a wireless communication element module which is assembled easily, economizes an accommodated space, prevents the signals from being lost, and dissipates the heat effectively for increasing transmission efficiency is an important issue in the mechanical design of the notebook computer industry.

### SUMMARY OF THE INVENTION

The present invention provides a multi-functional communication module for integrating a plurality of wireless communication elements for solving above drawbacks.

According to the claimed invention, a multi-functional communication module includes a base, a plurality of wireless communication elements disposed on the base, a plurality of antennas electrically connected to the plurality of wireless communication elements respectively so as to transmit wireless signals of the plurality of wireless communication elements, and a heat conductive component, a side of the heat conductive component being connected to the plurality of wireless communication elements so as to dissipate heat generated by the plurality of wireless communication elements.

According to the claimed invention, an electronic device includes a host comprising a main board, a screen connected to the host for displaying images, and a multi-functional communication module installed inside the screen. The multi-functional communication module includes a base, a plurality of wireless communication elements disposed on the base, a plurality of antennas electrically connected to the plurality of wireless communication elements respectively so as to transmit wireless signals of the plurality of wireless communication elements, and a heat conductive component, a side of the heat conductive component being connected to the plurality of wireless communication elements so as to dissipate heat generated by the plurality of wireless communication elements.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of an electronic device according to a preferred embodiment of the present invention.

FIG. 2 is a diagram of a multi-functional communication module installed inside the electronic device 10 according to the preferred embodiment of the present invention.

FIG. 3 is an enlarged diagram of the multi-functional communication module according to the preferred embodiment of the present invention.

FIG. 4 is a diagram of the multi-functional communication module according to another embodiment of the present invention.

FIG. 5 is a diagram of a plurality of antennas transmitting the wireless signals according to the preferred embodiment of the present invention.

FIG. 6 is a functional block diagram of the multi-functional communication module according to the preferred embodiment of the present invention.

### DETAILED DESCRIPTION

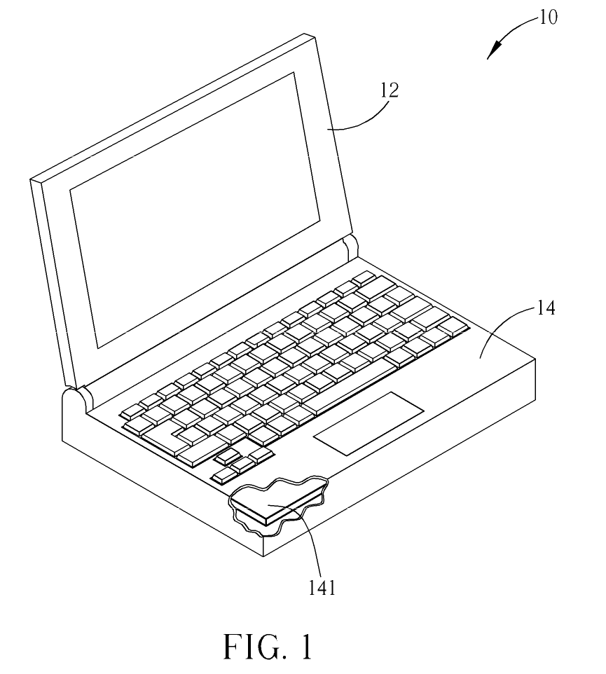

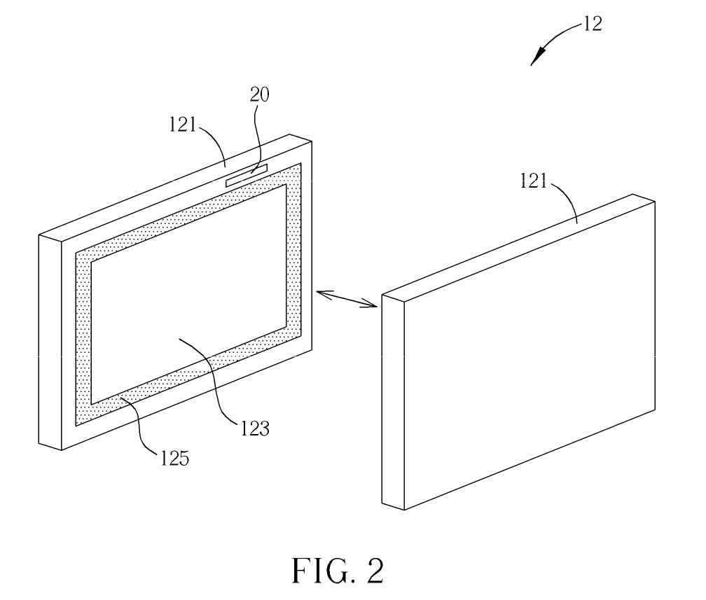

Please refer to FIG. 1. FIG. 1 is a diagram of an electronic device 10 according to a preferred embodiment of the present invention. The electronic device 10 can be a notebook computer. The electronic device 10 includes a screen 12 and a host 14. The host 14 includes a main board 141, and the screen 12 is connected to the host 14 for displaying images. Please refer to FIG. 2. FIG. 2 is a diagram of a multi-functional communication module 20 installed inside the electronic device 10 according to the preferred embodiment of the present invention. As shown in FIG. 2, the screen 12 includes a housing 121 and a panel 123 disposed on an inner side of the housing 121 for displaying the images. The screen 12 further includes a heat dissipating component 125 disposed between the housing 121 and the panel 123 so as to dissipate heat generated by the panel 123. Besides, the electronic device 10 further includes the multi-functional communication module 20 disposed inside the screen 12. The multi-functional communication module 20 can be disposed on a lateral side of the panel 123 inside the housing 121. Generally, the multi-functional communication module 20 can be disposed on an upper side of the panel 123, so that the multi-functional communication module 20 has preferred efficiency of wireless signals transmission. The heat dissipating component 125 can be made of metal material having greater heat conductive efficiency for dissipating the heat generated by the panel 123 and preventing the multi-functional communication module 20 from electromagnetic interference by the other electronic components. For example, the heat dissipating component 125 can be a metal thin film attached on a back of the panel 123, or can be a metal bracket disposed around the panel 123.

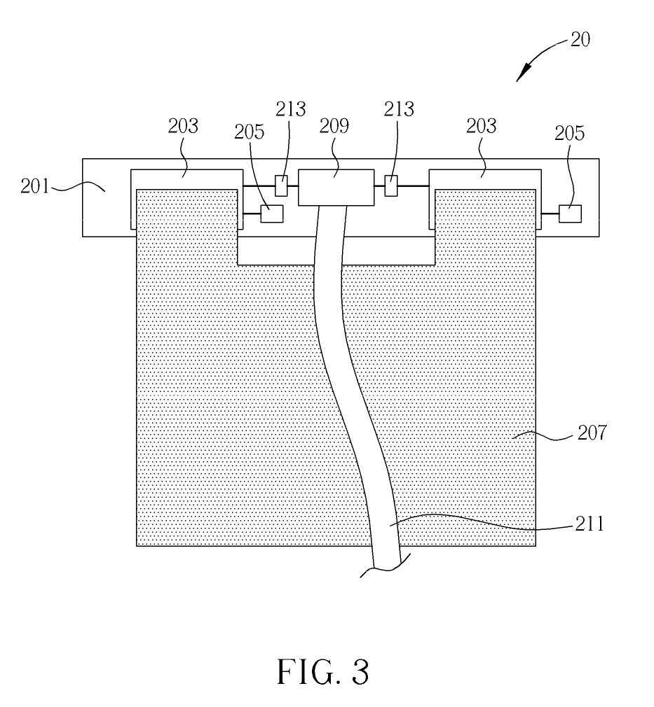

Please refer to FIG. 3. FIG. 3 is an enlarged diagram of the multi-functional communication module 20 according to the preferred embodiment of the present invention. The multi-functional communication module 20 includes a base 201, a plurality of wireless communication elements 203 disposed on the base 201, a plurality of antennas 205 electrically respectively connected to the plurality of wireless communication elements 203 for transmitting wireless signals of the plurality of wireless communication elements 203, and a heat conductive component 207. The multi-functional communication module 20 integrates the plurality of wireless communication elements 203 on a single base 201. Each wireless communication element 203 can be an electronic element with wireless communication function. The wireless communication function can conform to any kind of wireless transmission technique, such as WiFi, Bluetooth, 3G, UWB, DVBT, GPS, WIMAX, and so on. A side of the heat conductive component 207 is connected to the plurality of the wireless communication elements 203 so as to dissipate the heat generated by the plurality of wireless communication elements 203. The other side of the heat conductive component 207 is connected to the heat dissipating component 125 of the screen 12, so that the heat generated by the plurality of wireless communication elements 203 can be conducted to the heat dissipating component 125 via the heat conductive component 207 for increasing the heat dissipating efficiency of the multi-functional communication module 20. The heat conductive component 207 can be made of metal material having greater heat conducting efficiency, such as an aluminum foil and a metal coating layer, to dissipate the heat generated by the plurality of wireless communication elements 203 effectively. In addition, the heat conductive component 207 can further prevent the wireless signals transmitted by the plurality of antennas 205 from the electromagnetic interference.

The multi-functional communication module 20 further includes a connector 209 electrically connected to the plurality wireless communication elements 203, and a connecting cable 211 for transmitting the signals between the main board 141 and the plurality of wireless communication elements 203. An end of the connecting cable 211 is connected to the connector 209, and the other end of the connecting cable 211 is connected to the main board 141 of the host 14. The connecting cable 211 can be a flat cable, which is electrically connected to the connector 209 and the main board 141 by passing through a gap between the panel 123 and the housing 121, so as to transmit the signals between the plurality of wireless communication elements 203 and the main board 141. The multi-functional communication module 20 can further include a plurality of switches 213 electrically connected to the plurality of wireless communication elements 203 and the connector 209 for switching on and off the plurality of wireless communication elements 203, respectively. The switch 213 can be a low dropout (LDO) voltage adjuster.

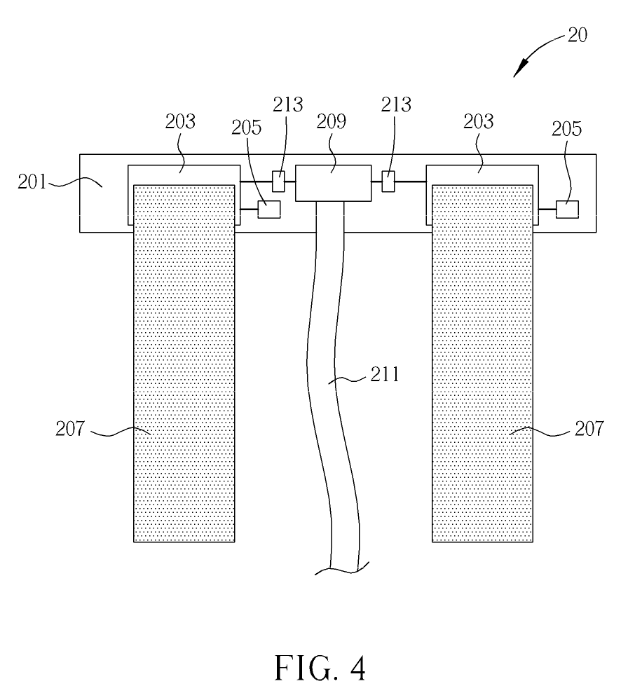

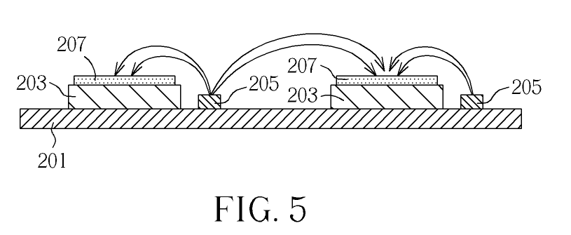

The heat conductive component 207 not only can be a single component, but also can be composed of a plurality of separated parts. Please refer to FIG. 4. FIG. 4 is a diagram of the multi-functional communication module 20 according to another embodiment of the present invention. When the heat conductive component 207 is composed of the plurality of separated parts, sides of the plurality of heat conductive components 207 are connected to the plurality of corresponding wireless communication elements 203, and the other sides of the plurality of heat conductive components 207 are connected to the heat dissipating component 125 so as to dissipate the heat generated by the plurality of wireless communication elements 203. The multi-functional communication module 20 of the present invention not only can dissipate the heat generated by the plurality of wireless communication elements 203 effectively, but also can prevent the wireless signals respectively transmitted by the plurality of antennas 205 from being interfered in the same communication frequency band. Please refer to FIG. 3, FIG. 4, and FIG. 5. FIG. 5 is a diagram of the plurality of antennas 205 transmitting the wireless signals according to the preferred embodiment of the present invention. The side of the heat conductive component 207 is connected to the plurality of wireless communication elements 203. The heat conductive component 207 covered on the plurality of wireless communication elements 203 and the plurality of antennas 205 are arranged alternately. As shown in FIG. 5, the wireless signals transmitted by each antenna 205 are grounded by the heat conductive component 207 disposed on two sides of the antenna 205, so that the wireless signals transmitted by the adjacent antennas 205 are not interfered with each other. That is to say, the heat conductive component 207 can increase signal isolation between the adjacent antennas 205, so as to prevent the plurality of antennas 205 transmitting the wireless signals in the same communication frequency band from the electromagnetic interference effectively.

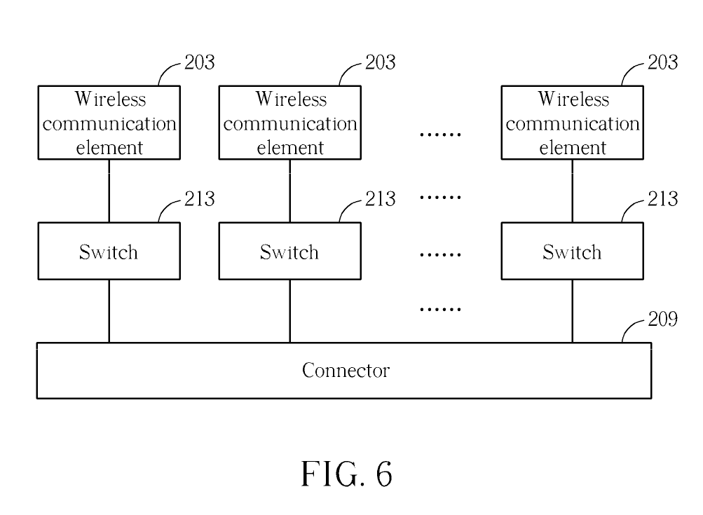

Please refer to FIG. 6. FIG. 6 is a functional block diagram of the multi-functional communication module 20 according to the preferred embodiment of the present invention. The plurality of wireless communication elements 203 can be electrically connected to the corresponding switches 213 to be respectively coupled to the connector 209. A control signal of the main board 141 is transmitted to the plurality of switches 213 via the connecting cable 211 and the connector 209 for switching on and off the corresponding wireless communication element 203. The switch 213 can be selectively installed between the corresponding wireless communication element 203 and the connector 209, which means the wireless communication element 203 can be electrically connected to the connector 209 directly and the switch 213 can be omitted for simplicity.

In conclusion, the multi-functional communication module 20 of the present invention includes the plurality of wireless communication elements 203 disposed on the base 201, and the connecting cable 211 and the connector 209 for integrating cables of the plurality of wireless communication elements 203 for convenient installation. The plurality of switches 213 of the multi-functional communication module 20 can respectively switch on and off the plurality of corresponding wireless communication elements 203 so as to economize power and to increase operating efficiency. The heat conductive component 207 of the multi-functional communication module 20 is connected between the plurality of wireless communication elements 203 and the heat dissipating component 125 of the screen 12. The heat conductive component 207 not only can dissipate the heat generated by the plurality of wireless communication elements 203 effectively, but also can prevent the wireless signals respectively transmitted by the plurality of antennas 205 from the electromagnetic interference. In addition, the multi-functional communication module 20 is disposed inside the screen 12 for economizing inner space of the host 14 and for increasing the heat dissipating efficiency of the main board 141. The plurality of wireless communication elements 203 can transmit the wireless signal rapidly via the plurality of antennas 205 due to close connection between the plurality of wireless communication elements 203 and the plurality of antennas 205 disposed inside the screen 12 of the electronic device 10, so that the signals transmitted between the plurality of wireless communication elements 203 and the plurality of antennas 205 are not lost easily and are not interfered by the electromagnetic interference.

Comparing to the prior art, the multi-functional communication module of the present invention is disposed inside the screen for decreasing the heat generated by the main board and for increasing the heat dissipating efficiency of the thermal module, such as a fan, on the main board and for increasing the operating efficiency and stability of the main board. The connecting cable of the multi-functional communication module of the present invention is assembled easily. The signals transmitted between the plurality of wireless communication elements and the plurality of antennas are not interfered by the other electronic components on the main board because the plurality of wireless communication elements is disposed inside the screen. In addition, the heat conductive component of the multi-functional communication module of the present invention not only can dissipate the heat generated by the plurality of wireless communication elements effectively, but also can increase the signal isolation between the adjacent antennas so as to prevent the adjacent antennas from interference. Thus, the multi-functional communication module of the present invention has greater transmission speed than the conventional mechanism of Co-Existence and time sharing techniques.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A multi-functional communication module comprising:
a base;
a plurality of wireless communication elements disposed on the base;
a plurality of antennas electrically connected to the plurality of wireless communication elements respectively so as to transmit wireless signals of the plurality of wireless communication elements; and
a heat conductive component, a side of the heat conductive component being connected to the plurality of wireless communication elements so as to dissipate heat generated by the plurality of wireless communication elements.

2. The multi-functional communication module of claim 1 further comprising:
a connector electrically connected to the plurality of wireless communication elements; and
a connecting cable, an end of the connecting cable being connected to the connector so as to transmit the wireless signals of the plurality of wireless communication elements.

3. The multi-functional communication module of claim 2 further comprising:
a plurality of switches electrically connected to the plurality of wireless communication elements and the connector respectively for respectively switching on and off the plurality of wireless communication elements.

4. The multi-functional communication module of claim 3, wherein the switch is a low dropout (LDO) voltage adjuster.

5. The multi-functional communication module of claim 1, wherein the heat conductive component comprises a plurality of separated parts respectively connected to the plurality of wireless communication elements so as to dissipate the heat generated by the plurality of wireless communication elements, respectively.

6. The multi-functional communication module of claim 1, wherein the heat conductive component is made of metal material.

7. The multi-functional communication module of claim 6, wherein the heat conductive component is an aluminum foil.

8. The multi-functional communication module of claim 6, wherein the heat conductive component is a metal coating layer.

9. The multi-functional communication module of claim 6, wherein the heat conductive component is further for preventing the wireless signals transmitted by the plurality of wireless communication elements from electromagnetic interference, respectively.

10. An electronic device comprising:
a host comprising a main board;
a screen connected to the host for displaying images; and
a multi-functional communication module installed inside the screen, the multi-functional communication module comprising:
a base;
a plurality of wireless communication elements disposed on the base;
a plurality of antennas electrically connected to the plurality of wireless communication elements respectively so as to transmit wireless signals of the plurality of wireless communication elements; and
a heat conductive component, a side of the heat conductive component being connected to the plurality of wireless communication elements so as to dissipate heat generated by the plurality of wireless communication elements.

11. The electronic device of claim 10, wherein the screen comprises:
a housing;
a panel disposed inside the housing for displaying the images; and
a heat dissipating component disposed between the housing and the panel so as to dissipate heat generated by the panel.

12. The electronic device of claim 11, wherein the heat dissipating component is connected to the other side of the heat conductive component of the multi-functional communication module so that the heat generated by the plurality of wireless communication elements is conducted to the heat dissipating component via the heat conductive component.

13. The electronic device of claim 11, wherein the heat dissipating component is made of metal material.

14. The electronic device of claim 10, wherein the multi-functional communication module further comprises:
a connector electrically connected to the plurality of wireless communication elements; and
a connecting cable, an end of the connecting cable being connected to the connector, and the other end of the connecting cable being connected to the main board so as to transmit the wireless signals between the plurality of wireless communication elements and the main board.

15. The electronic device of claim 14, wherein the multi-functional communication module further comprises a plurality of switches electrically connected to the plurality of wireless communication elements and the connector respectively, so as to respectively switching on and off the plurality of wireless communication elements.

16. The electronic device of claim 15, wherein the switch is a low dropout voltage adjuster.

17. The electronic device of claim 10, wherein the heat conductive component comprises a plurality of separated parts respectively connected to the plurality of wireless communication elements so as to dissipate the heat generated by the plurality of wireless communication elements respectively.

18. The electronic device of claim 10, wherein the heat conductive component is made of metal material.

19. The electronic device of claim 18, wherein the heat conductive component is an aluminum foil or a metal coating layer.

20. The electronic device of claim 18, wherein the heat conductive component is further for preventing the wireless signals transmitted by the plurality of wireless communication elements from electromagnetic interference, respectively.
